(19) United States
(12) Patent Application Publication
(10) Pub. No.: US 2026/0221763 A1
(43) Pub. Date: Jul. 30, 2026

(54) ELECTROSTATIC DISCHARGE PROTECTION FOR HIGH VOLTAGE POWER PINS IN DEEP SUB-MICRON PROCESS NODES

(71) Applicant: QUALCOMM Incorporated, San Diego, CA (US)

(72) Inventor: Shamim AHMED, Mesa, AZ (US)

(21) Appl. No.: 19/037,056

(22) Filed: Jan. 24, 2025

(51) Int. Cl. H02H 9/04

(52) U.S. Cl. CPC H02H 9/046

(57) ABSTRACT

An ESD protection circuit has a first voltage divider, a second voltage divider and two clamp circuits. The first voltage divider may include a plurality of resistors coupled in series between a first power rail and a second power rail. In one example, two resistors in the plurality of resistors may be connected through a first node. The second voltage divider may include a plurality of capacitors coupled in series between the first power rail and the second power rail. In one example, two capacitors in the plurality of capacitors are connected through the first node. The two clamp circuits may be coupled in series between the first power rail and the second power rail. The two clamp circuits may be connected through a second node that is coupled to a third power rail. The third power rail may have a voltage defined by the voltage at the first node.

### TECHNICAL FIELD

The present disclosure generally relates to interface circuits for integrated circuits and, more particularly, to electrostatic discharge protection circuits that can enhance charged-device model robustness of integrated circuit devices.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever. Continuous service enhancements require the advancement of process technologies that can provide integrated circuit (IC) devices with ever increasing performance and transistor densities.

Advancements in process technologies tend to reduce transistor gate length and other feature sizes with IC devices. Reductions in gate length and feature sizes can increase the susceptibility of IC devices to electrostatic discharge (ESD) events. IC devices often include ESD protection circuits that can protect interface circuits during different types of ESD events. IC devices may be tested to ensure that they meet minimum industry standards regarding ESD protection. IC device qualification processes may include testing the susceptibility of the IC device to ESD events based on a human-body model (HBM) or based on a charged-device model (CDM) characterization of ESD events. Some ESD protection circuits are based on or evaluated using an HBM or a CDM. The HBM is intended to characterize the susceptibility of devices to damage from ESD events of ±1 kVolt resulting from human touching of an electronic device. The CDM is intended to characterize the susceptibility of devices to damage from ESD events of ±250 Volts that relate to sudden discharges of energy accumulated in an IC chip or package through direct contact charging or field-induced charging.

Changes in certain aspects of large-scale IC designs and semiconductor manufacturing processes, including reductions in process minimum feature size can create new or different challenges in protecting IC devices from ESD events. Accordingly, there is an ongoing need for improvements in ESD protection for IC interface circuits.

### SUMMARY

Certain aspects of the disclosure relate to systems, apparatus, methods and techniques that can provide enhanced electrostatic discharge (ESD) protection circuits in certain IC devices, including IC devices that employ or interface with circuits in multiple voltage domains. Some aspects disclosed herein are applicable to interface circuits in an IC. Some examples disclosed herein are applicable to the protection of circuits at the boundary between a low-voltage domain that is used to implement certain core features of the IC device and a higher-voltage domain that is used for device input and output (I/O).

In one aspect of the disclosure, an ESD protection circuit includes a first voltage divider, a second voltage divider and two clamp circuits. The first voltage divider may include a plurality of resistors coupled in series between a first power rail and a second power rail. In one example, two resistors in the plurality of resistors may be connected through a first node. The second voltage divider may include a plurality of capacitors coupled in series between the first power rail and the second power rail. In one example, two capacitors in the plurality of capacitors are connected through the first node. The two clamp circuits may be coupled in series between the first power rail and the second power rail. The two clamp circuits may be connected through a second node that is coupled to a third power rail. The third power rail may have a voltage defined by the voltage at the first node.

In one aspect of the disclosure, an apparatus has means for clamping a power rail, means for providing power through an internal power rail and means for providing a low impedance path for high-frequency currents. The means for clamping a power rail may have two clamp circuits that are coupled in series between a first power rail and a second power rail. The means for providing power through an internal power rail may include a first voltage divider that comprises a plurality of resistors coupled in series between the first power rail and the second power rail. The means for providing a low impedance path for high-frequency currents may be implemented as a second voltage divider that includes a plurality of capacitors coupled in series between the first power rail and the second power rail.

In one aspect of the disclosure, a method for providing ESD protection in an IC device includes providing power to a circuit through a first power rail and a second power rail, providing power through a third power rail at a voltage controlled by a first voltage divider that comprises a plurality of resistors coupled in series between the first power rail and the second power rail, and providing a low impedance path for high-frequency currents using a second voltage divider comprising a plurality of capacitors that is coupled in series between the first power rail and the second power rail. Two capacitors in the plurality of capacitors may be connected through the first node. Two clamp circuits may be coupled in series between the first power rail and the second power rail. A common node connecting the two clamp circuits may be coupled to the third power rail.

In certain examples, the sum of the resistances provided by plurality of resistors lies in the megaohm range.

In certain examples, the ESD protection circuit has a first transistor that has a drain coupled to the first power rail, a source coupled to the third power rail and a gate coupled to the first node.

In certain examples, the ESD protection circuit may have a second transistor that has a drain coupled to the third power rail, and a source and a gate coupled to the second power rail.

In certain examples, the ESD protection circuit may have a resistive load coupled between the third power rail and the second power rail.

In certain examples, the ESD protection circuit may have a resistor coupled between the third power rail and the second power rail through a transistor switch. The transistor switch may be turned on as voltage difference between the first power rail and the second power rail is ramped from zero to a nominal operating voltage.

In certain examples, the ESD protection circuit has a capacitor coupled between the source of the first transistor and the second power rail. The second power rail may be coupled to a ground reference.

### BRIEF DESCRIPTION OF THE DRAWINGS

FIG. 1 illustrates an example of an electrostatic discharge (ESD) event.

FIG. 2 illustrates a first example of an interface circuit that provides ESD protection in an IC device.

FIG. 3 illustrates a clamp structure that may be used to protect a high voltage package pin of a SoC developed in a small process node.

FIG. 4 illustrates an example of a clamp structure that has been adapted or configured in accordance with certain aspects of this disclosure.

FIG. 5 illustrates a first example of an internal power supply may be used in a clamp structure that has been adapted or configured in accordance with certain aspects of this disclosure.

FIG. 6 illustrates a second example of an internal power supply may be used in a clamp structure that has been adapted or configured in accordance with certain aspects of this disclosure.

FIG. 7 is a flow diagram illustrating a method for providing ESD protection in accordance with certain aspects disclosed herein.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the Figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications).

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain examples of circuits disclosed herein are illustrated or described as being implemented using certain combinations of P-type metal-oxide-semiconductor (PMOS) transistors and N-type metal-oxide-semiconductor (NMOS) transistors. These circuits are provided by way of example only, and it is contemplated that the concepts disclosed herein can be implemented in circuits that use different combinations of metal-oxide-semiconductor (MOS) transistors, including complementary metal-oxide-semiconductor (CMOS) digital circuits. Circuits that include NMOS or PMOS transistors are typically coupled to the rails of a power supply. The power supply provides a current that flows from a higher voltage rail to a lower voltage rail. A rail may include some combination of conductors, wires, connectors and other types of interconnect. For the purposes of this description, the higher voltage rail may be referenced as “VDD” or “V_{DD}” and the lower voltage rail may be referred to as Ground, VSS or V_{SS}. In some implementations, power may be provided to certain circuits through more than two power rails, including power rails at different voltages. In one example, power may be supplied from a first rail (V_{DDH}) at a higher voltage with respect to Ground (V_{SS}), and from a second rail (V_{DDL}) at a voltage that is lower than the V_{DDH} voltage.

Evolution in transistor technology has led to decreased gate oxide thickness and lower operating voltages. The reduction in gate oxide thickness reduces the maximum gate-drain, gate-source and gate-bulk voltage that can be withstood by the device during an ESD event. Moreover, ICs often provide multiple voltage domains for power saving purposes. For example, higher voltage domains are sometimes needed for interfacing with external devices, while core circuits can generally operate at the lower voltage levels available in lower voltage domains. A stack of low threshold voltage transistors can be used as I/O drivers that switch within voltage ranges greater than the voltage ranges used by core circuits.

Electrostatic discharge (ESD) events can generate voltages or currents within an IC device that exceed rated operating parameters, including rated operating voltage. Rated operating voltage may lie within a nominal operating range of voltage levels defined for certain devices, circuits or input/out (I/O) pads. As used herein, an I/O pad may be defined as a structure that is part of a coupling that conducts signals between internal circuits of the core of an IC device and the external terminals, connectors or pins of a chip package that carries the IC device. In one example, I/O pads may be coupled to external terminals, connectors or pins through wires that are thermosonically bonded to the I/O pads. In another example, I/O pads may be coupled to external terminals, connectors or pins through solder balls that contact the I/O pads. Without adequate protection, circuits can be damaged near I/O pads or near other sources or entry points of the ESD events. ESD events may occur due to some combination of grounding failures, handling and/or accumulation of static charge at a surface or point of contact near the IC device.

Certain aspects of this disclosure are described in relation to a charged-device model (CDM) characterization of ESD events. The CDM relates to an ESD event that occurs when a chip, chip carrier or package that includes an IC device contacts a low impedance electrical path. A sudden discharge of energy can occur if the chip, chip carrier or package is carrying an accumulated electrostatic charge, causing a high-voltage pulse or spike at I/O pads of the IC device. The voltage observable at one or more I/O pads may exceed rated tolerances for transistors in the IC device and can cause breakdown or other damage to transistor gates and other features of the IC device if adequate ESD protection is not provided.

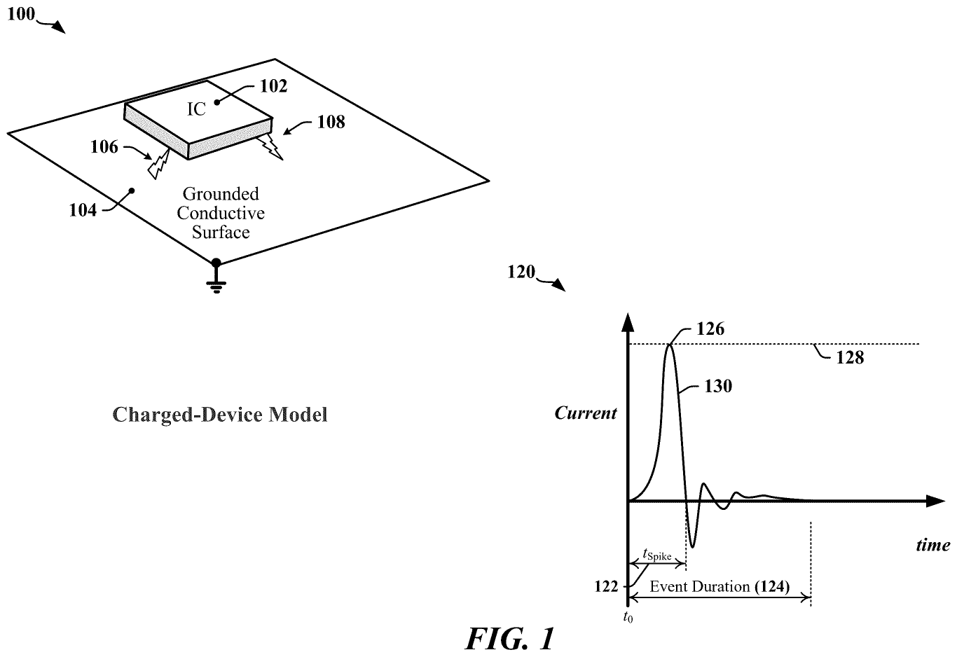

FIG. 1 illustrates an example of an ESD event 100 that may be characterized as a CDM event. The ESD event 100 occurs as an IC device 102 is placed on a metal or other conductive surface 104. In some examples, this type of ESD event 100 may occur at a manufacturing or assembly facility when IC devices on chips, chip carriers or packages are accumulated, assembled or sorted before being placed and bonded or soldered to a circuit board. In some examples, this type of ESD event 100 may occur at a manufacturing facility when IC devices 102 are picked up by a robot and placed on a circuit board or in a shipment package, where the robot may serve as the conductive surface 104. As the IC device 102 is placed on the conductive surface 104, accumulated charge in the IC device 102 may be discharged to the conductive surface 104 through one or more potential gradients 106, 108. Discharge may occur before or after I/O pins or pads are directly coupled to the conductive surface 104.

The graph 120 illustrates an example of a type of ESD event 100 as characterized by a CDM. In this example, a high percentage of the electrostatic energy accumulated in the IC device 102 is discharged over a short period of time 122 in an initial pulse or spike 130. In one example, the ESD event 100 may have a duration 124 that lasts for approximately 5 nanoseconds with the initial spike 130 ending after approximately 1 nanosecond. In some instances, the discharge may result in a first peak 126 at a current level 128 of 4.7 amps or more. The current spike flowing through an I/O pad of the IC device 102 may cause a correspondent spike in voltage in the interface circuits of the IC device 102.

Current ESD protection schemes employed to protect output drivers typically include diodes connected between an interface pad and output power supply rails and may include a clamping circuit through the diode discharge series path that can carry the ESD current and thereby prevent damage to driver devices.

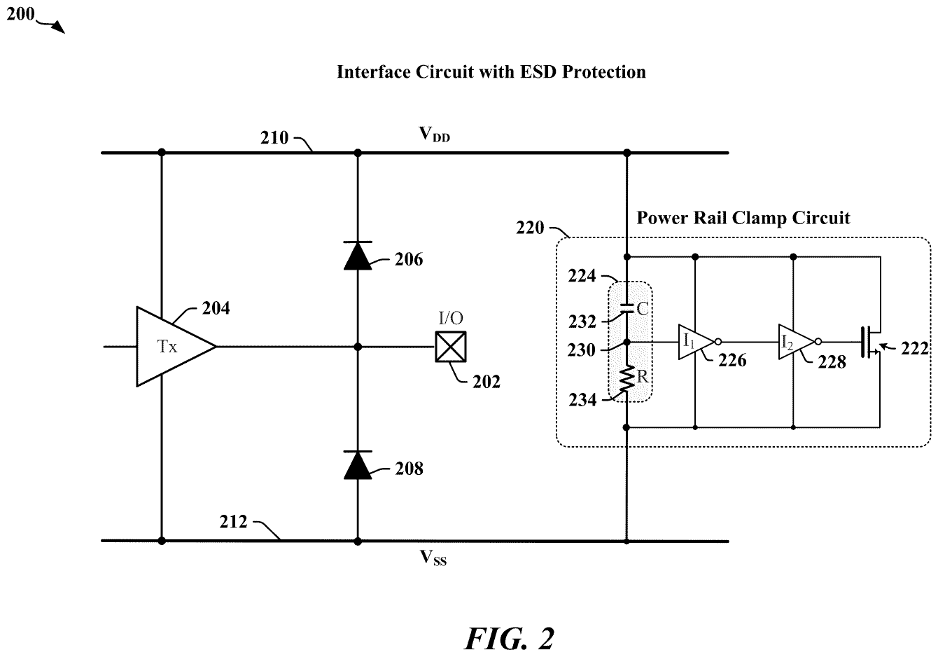

FIG. 2 illustrates an example of an interface circuit 200 that provides ESD protection in an IC device. The interface circuit 200 includes a driver 204 that can be used to transmit signals through an I/O pad 202 of the IC device. The driver 204 may be configured to provide an output that switches between a voltage levels defined for a power rail (V_{DD} 210) and for a ground reference (V_{SS} 212). ESD protection is provided by a pair of diodes 206, 208. A first diode 206 is coupled to V_{DD} 210 and to the I/O pad 202 and is reverse biased when the voltage of the I/O pad 202 remains below V_{DD} 210. A second diode 208 is coupled to V_{SS} 212 and to the I/O pad 202 and is reverse biased when the voltage of the I/O pad 202 remains above V_{SS} 212. An ESD event may cause a current surge through the I/O pad 202 and one or more interconnects between the I/O pad 202 and the driver 204. The interconnects have a low resistance that can significantly change the voltage of the I/O pad 202 when conducting a multi-amp ESD surge current. The change in voltage may be sufficient to forward bias one of the diodes 206, 208, thereby enabling the ESD surge current to be diverted to V_{DD} 210 or V_{SS} 212 away from the driver 204 and other circuits of the IC device.

The diversion of the ESD surge current to V_{DD} 210 or V_{SS} 212 can increase the voltage difference between V_{DD} 210 and V_{SS} 212, which can stress or damage devices in the interface circuit 200 if left unchecked. The illustrated interface circuit 200 includes a power rail clamping circuit 220 that is coupled between V_{DD} 210 and V_{SS} 212. The power rail clamping circuit 220 includes an N-type metal-oxide-semiconductor (NMOS) transistor 222 that is biased by a serial resistor-capacitor (RC) network 224. The RC network 224 has a capacitor 232 coupled in series with a resistor 234. In the illustrated example, the serial RC network 224 is coupled between power supply V_{DD} 210 and the ground reference V_{SS} 212. A node 230 coupling the capacitor 232 and the resistor 234 is coupled to the gate of the transistor 222 through a buffer amplifier arrangement including first and second series-connected inverters 226, 228. The power rail clamping circuit 220 ensures a low impedance path from V_{DD} 210 to V_{SS} 212 when an ESD pulse applied to the I/O pad 202 causes the voltage difference between V_{DD} 210 and V_{SS} 212 to increase.

In one example, a rising voltage on V_{DD} 210 is coupled through the capacitor 232 to the input of the first inverter 226 forcing its output to a low voltage signaling state. In response, the output of the second inverter 228 goes high turning on the transistor 222. When the transistor 222 turns on, the ESD current can begin to flow between V_{DD} 210 and V_{SS} 212.

In the illustrated interface circuit 200, the driver 204 is constructed using devices that can tolerate the voltage swing between V_{DD} 210 and V_{SS} 212 under nominal operating conditions. More particularly, it can be assumed that the process technology or technologies employed to manufacture the interface circuit 200 can provide the transistor size, operating voltage and switching speed necessary to construct the illustrated driver 204 in accordance with design specifications. The circuits of the power rail clamping circuit 220 may be constructed using the process node associated with the driver 204.

A clamping circuit such as the power rail clamping circuit 220 may be difficult to implement in an SoC that provides multiple voltage domains. For example, the process technology used for core circuits operating at lower voltage levels available in core voltage domains may be incapable of manufacturing devices for a clamping circuit to be used at an interface with a higher voltage domain. Devices in such a clamping circuit may be exposed to voltage levels that exceed safe operating area (SOA) limits of the process technology used for manufacturing the core circuits.

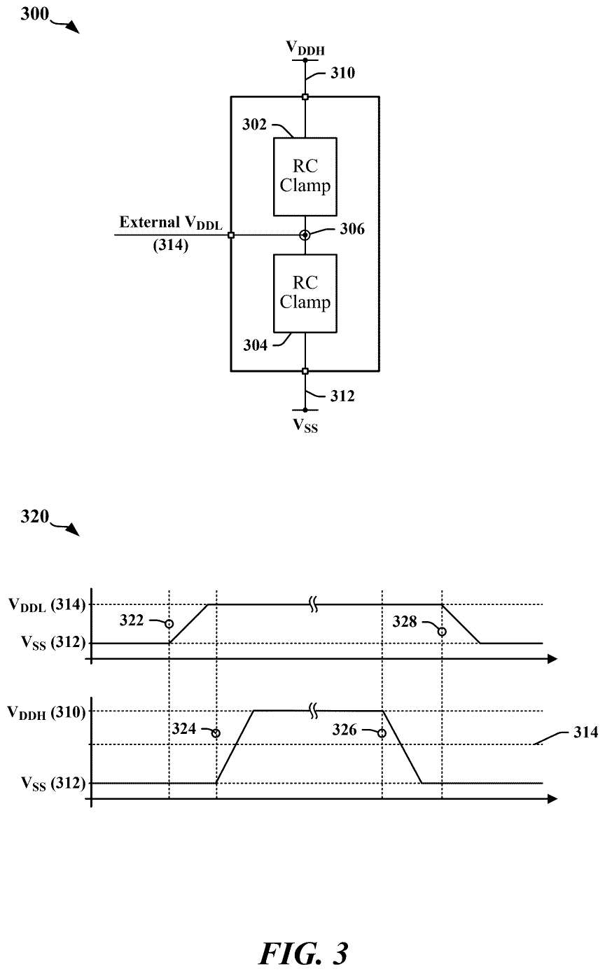

FIG. 3 illustrates a RC clamp structure 300 that may be used to protect a high voltage package pin of a SoC developed in a small process node. The RC clamp structure 300 includes a cascade of RC clamps. In the illustrated example, two RC clamps 302, 304 are coupled in series between a pair of power rails including a first power supply rail (the V_{DDH} rail 310) operated at a higher voltage level and a second power supply rail that provides a ground reference (V_{SS} 312). The two RC clamps 302, 304 are coupled at a center node 306 that is further coupled to a third power supply rail (the V_{DDL} rail 314) that provides power at a voltage that is lower than the nominal voltage level of the V_{DDH} rail 310. In one example, the RC clamp structure 300 may be used to protect a high voltage package pin for a SOC, where the pin is rated for 3.3V operation and the related circuits of the SoC are developed in a small process node rated for 1.8V operation. In this latter example, there may be a lack of a high voltage devices available to implement a single RC clamp. In some instances, high voltage devices may be available at the cost of extra mask layers and associated increased manufacturing (silicon) expense.

A cascaded RC clamp can be used when an external low voltage supply is available. In the illustrated example, the RC clamp structure 300 can be used when V_{DDL} 314 is ramped up to its nominal voltage level before the voltage on the V_{DDH} rail 310 exceeds the nominal voltage level specified or defined for the V_{DDL} rail 314. In one example, the RC clamps 302, 304 may be implemented using MOS devices that are rated for 1.8V and cannot sustain power supply levels of 3.3V. During an ESD event, a clamped 3.3V may be applied to at least one of the RC clamps 302, 304 if the V_{DDL} rail 314 has not attained its nominal 1.8V level.

The timing diagram in FIG. 3 illustrates an example of a power supply ramp sequence 320 required to maintain the reliability of the devices used in the RC clamps 302, 304 that are developed in a small process node. In the illustrated example, the voltage of the V_{DDL} rail 314 begins ramping up at a first point in time 322 and achieves its nominal operating voltage level before the higher voltage power supply begins ramping up at a second point in time 324. The higher-voltage power supply begins ramping down at a third point in time 326 and reaches a minimum voltage level (e.g., V_{SS} 312) before the lower-voltage power supply begins ramping down a fourth point in time 328.

In conventional systems, the power supply ramp sequence 320 can typically be maintained and/or guaranteed only when an external power management IC (PMIC) is used to control and/or provide power supplies. The RC clamp structure 300 may be unusable when external control of ramp up sequences is unavailable or indeterminate.

An ESD protection circuit power supply provided in accordance with certain aspects of this disclosure includes a power supply that can provide a power rail for a cascaded RC clamp structure. In one example, an SoC may receive power at a V_{DDH} voltage level=3.3V and may internally generate a power rail at a V_{DDL} voltage level =1.8V. In certain implementations, the internally generated power rail ramps concurrently with the external power supply thereby preventing exposure of low-voltage devices to overvoltage conditions.

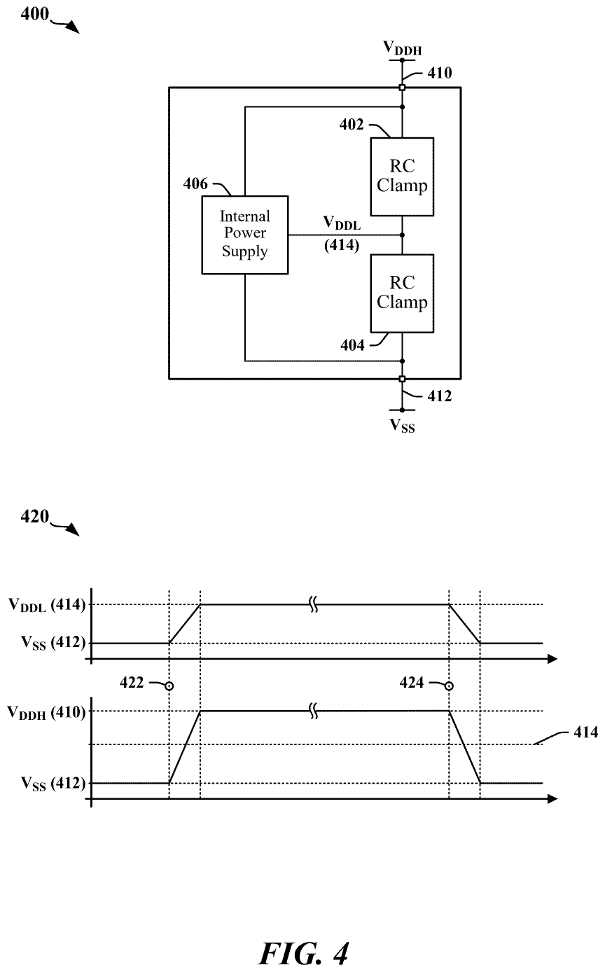

FIG. 4 illustrates an example of a RC clamp structure 400 that has been adapted or configured in accordance with certain aspects of this disclosure. The RC clamp structure 400 may be configured to protect a high voltage package pin of a SoC developed in a small process node. In one aspect, the RC clamp structure 400 includes an internally-generated power supply 406 (the V_{DDL} rail 414) from an externally-provided power supply (the V_{DDH} rail 410). In one aspect, the V_{DDL} rail 414 can closely follow the timing of the voltage ramp of the V_{DDH} rail 410 such that the voltage levels of V_{DDL} and (V_{DDH}-V_{DDL}) lie within the SOA limits defined for device voltages within the RC clamp 402, 404. This combination of power supplies enables the safe usage of a cascaded RC clamp to protect the high voltage pin from ESD strikes.

In the illustrated example, two RC clamps 402, 404 are coupled in series between the higher-voltage V_{DDH} rail 410 and a rail that provides a ground reference (V_{SS} 412). The two RC clamps 402, 404 are further coupled to the lower-voltage V_{DDL} rail 414. In one example, the RC clamp structure 400 can be used to protect a high voltage package pin for a SoC that is rated for 3.3V operation, including when the related circuits of the SoC are developed in a small process node.

In certain implementations, the internal power supply 406 may provide the V_{DDL} rail 414 at a voltage that is proportionate to the V_{DDH} rail 410 during the voltage ramp of the V_{DDH} rail 410. In some implementations, the internal power supply 406 may regulate the voltage of the V_{DDL} rail 414 under nominal operating conditions. In the illustrated example, V_{DDL} rail 414 is ramped up to its nominal voltage level concurrently with the V_{DDH} rail 410. In certain implementations, the internal power supply 406 includes a voltage divider that is configured to ensure that the difference between the voltage of the V_{DDL} rail 414 and the voltage of the V_{DDH} rail 410 cannot exceed the SOA limits defined for device voltages within the RC clamp 402, 404 under expected operating conditions. In one example, the RC clamps 402, 404 may be implemented using MOS devices that are rated for 1.8V operation and cannot sustain power supply levels of 3.3V.

The timing diagram in FIG. 4 illustrates an example of a power supply ramp sequence 420 associated with the RC clamp structure 400 and the internal power supply 406. In the illustrated example, the V_{DDL} rail 414 is derived from the V_{DDH} rail 410 and ramps as the V_{DDH} rail 410 ramps. The V_{DDH} rail 410 begins ramping up at a first point in time 422, concurrently initiating the ramp up of the V_{DDL} rail 414. The V_{DDH} rail 410 begins ramping down at a second point in time 424, concurrently initiating the ramp down of the V_{DDL} rail 414.

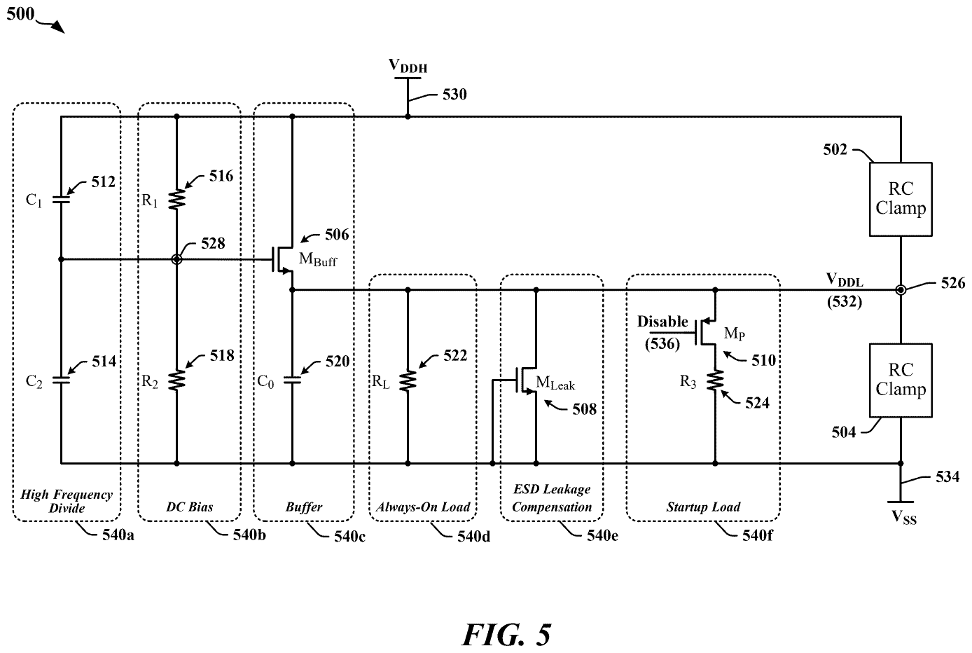

FIG. 5 illustrates a first example of an internal power supply 500 that can provide an internally-generated power rail (the V_{DDL} rail 532) to a cascaded RC clamp structure that includes cascaded RC clamps 502, 504. The RC clamps 502, 504 are coupled between an externally-provided power rail (the V_{DDH} rail 530) and a ground reference (the V_{SS} rail 534). Each of the RC clamps 502, 504 is coupled to a common node 526 that is also coupled to the V_{DDL} rail 532.

The internal power supply 500 may be considered to include at least six stages 540a-540f. A first stage 540a is configured as a high-frequency voltage divider. Capacitors 512 and 514 are coupled in series between the V_{DDH} rail 530 and the V_{SS} rail 534. Capacitors 512 and 514 are coupled to one another through a node 528 that is also coupled to the gate of a buffer transistor 506. The buffer transistor 506 is provided in the third stage 540c. The capacitors 512 and 514 are configured as a capacitive divider that can provide a low impedance path for high-frequency currents, including currents generated by a fast ESD strike on the V_{DDH} rail 530. In some implementations, this low impedance path may be configured to protect the buffer transistor 506 during ESD events.

A second stage 540b is configured to provide a direct current (DC) bias. Resistors 516 and 518 are coupled in series between the V_{DDH} rail 530 and the V_{SS} rail 534. The resistors 516 and 518 may be configured to establish a DC bias at the gate of the buffer transistor 506. The buffer transistor 506 may be configured as a source follower that drives the V_{DDL} rail 532. In the illustrated example, the resistors 516 and 518 are configured as a voltage divider that establish a voltage at the node 528 that is coupled to the gate of a buffer transistor 506. Accordingly, the voltage of the V_{DDL} rail 532 may be defined by the voltage at node 528. The resistances provided by resistors 516 and 518 may be configured to ensure that the voltage difference between the V_{DDL} rail 532 and V_{SS} rail 534 remains within the SOA limit defined for devices used to implement the RC clamps 502, 504. The resistances provided by the resistors 516 and 518 may be further configured to ensure that the voltage difference between the V_{DDH} rail 530 and the V_{DDL} rail 532 remains within the SOA limit defined for devices used to implement the RC clamps 502, 504. In one example, the SOA limit defined for devices used to implement the RC clamps 502, 504 may be limited to a voltage range of less than 1.98V under all anticipated operating conditions. In one example, the sum of the resistances provided by resistors 516 and 518 lies in the megaohm (MΩ) range and may be configured to minimize quiescent currents. In one example, the combination of the resistances provided by resistors 516 and 518 provides a resistance of about 1.7 MΩ. In another example, the resistance exceeds or equals about 1 MΩ. In other examples, the combination of the resistances provided by resistors 516 and 518 provides a resistance that is greater than or less than 1.7 MΩ.

The RC network comprising resistor 516 and capacitor 512 and the RC network comprising resistor 518 and capacitor 514 act as low impedance dividers when a fast voltage ramp is applied to the V_{DDH} rail 530. These RC networks can help ensure that the V_{DDL} rail 532 follows the V_{DDH} rail 530.

The large resistances provided by resistors 516 and 518 result in a large gate impedance for the buffer transistor 506 and the gate-to-source load current is typically insignificant. In some implementations, the buffer transistor 506 may be implemented with a size that is sufficient to provide a low impedance at its source and thereby provide some source-drain load current.

In the illustrated third stage 540c, the source of the buffer transistor 506 is coupled to the V_{SS} rail 534 through a capacitor 520. The capacitor 520 can be configured to shunt transients to the V_{SS} rail 534.

A fourth stage 540d is configured to provide an “always-on” load. The fourth stage 540d includes a load resistor 522 that sinks a non-switchable, always-on load current. The load resistor 522 may be configured to ensure that impedance at the source of the buffer transistor 506 remains below a desired maximum level when current drawn from the V_{DDL} rail 532 by the RC clamps 502, 504 and/or other stages 540e, 540f is very small. A very low current draw can be expected at low temperatures (e.g., −40° C.).

A fifth stage 540e is configured to compensate for leakage associated with the buffer transistor 506 at high temperature. The buffer transistor 506 is typically a relatively large transistor and the leakage associated with the buffer transistor 506 at high temperature can pull the voltage of the V_{DDL} rail 532 towards the voltage of the V_{DDH} rail 530 if the load current is too small. It is typically not desirable to reduce the resistance provided by the load resistor 522 since the load resistor 522 always consumes some level of current. A leakage compensation transistor 508 provided in the fifth stage 540e may be a replica of the buffer transistor 506 or of the same type of device as the buffer transistor 506. The leakage compensation transistor 508 can provide a current path that serves to compensate for the leakage of the buffer transistor 506 and/or other devices at higher temperatures.

A sixth stage 540f is configured to provide a startup load. During circuit initialization, when the voltage of the V_{DDH} rail 530 is ramping up, the load current through the buffer transistor 506 needs to be sufficiently high to minimize overshoot allowed for the V_{DDL} rail 532. A control signal (the Disable signal 536 in the current example) coupled to the gate of a startup transistor 510 may be expected to be in a low signaling state as the circuit is initialized. A low signaling state at the gate of the startup transistor 510 causes the startup transistor 510 to be turned on when the V_{DDL} rail 532 is at a sufficient voltage level (i.e. above the threshold voltage of the transistor 510). A startup load resistor 524 coupled to the drain of the startup transistor 510 can be used to configure the magnitude of the startup current. The startup load resistor 524 may provide a resistance that lies in the kiloohm (kΩ) range. The startup load resistor 524 may provide a resistance that lies in the kiloohm (kΩ) range. In one example, the startup load resistor 524 provides a resistance of 200 kΩ. In other examples, the startup load resistor 524 can be selected or configured to provide a resistance that is greater than or less than 200 kΩ. At some point after startup has been sufficiently completed the Disable signal 536 may be driven to a high signaling state to turn off the startup transistor 510 and terminate the startup current in order to conserve power. In one example, the startup may be sufficiently completed when the V_{DDH} rail 530 has reached a steady state or nominal voltage level.

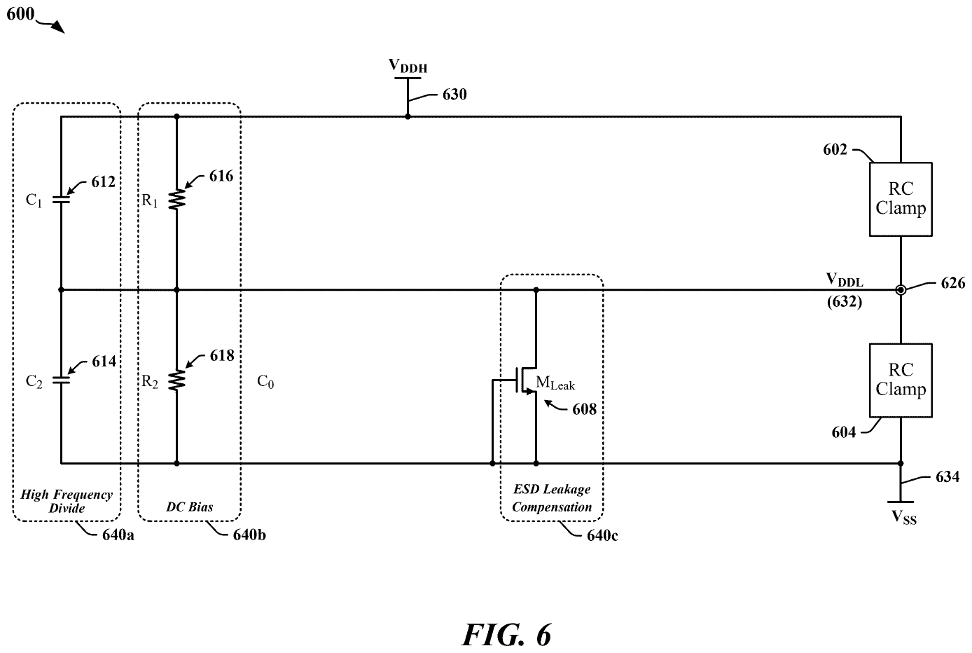

FIG. 6 illustrates a second example of an internal power supply 600 that can provide an internally-generated power rail (the V_{DDL} rail 632) to a cascaded RC clamp structure that includes RC clamps 602, 604. The RC clamps 602, 604 are coupled between an externally-provided power rail (the V_{DDH} rail 630) and a ground reference (the V_{SS} rail 634). Each of the RC clamps 602, 604 is coupled through a common node 626 to the internal V_{DDL} rail 632. The internal power supply 600 differs from the internal power supply 500 in that it includes fewer stages 640a-640c and omits the buffer stage and associated buffer transistor.

A first stage 640a is configured as a high-frequency voltage divider. Capacitors 612 and 614 are coupled in series between the V_{DDH} rail 630 and the V_{SS} rail 634. A first capacitor 612 is coupled between the V_{DDH} rail 630 and the internal V_{DDL} rail 632. A second capacitor 614 is coupled between the V_{DDL} rail 632 and the V_{SS} rail 634. The resultant capacitive divider provides a low impedance path for high-frequency currents, including currents generated by a fast ESD strike on the V_{DDH} rail 630.

A second stage 640b is configured as a voltage divider. Resistors 616 and 618 are coupled in series between the V_{DDH} rail 630 and the V_{SS} rail 634. A first resistor 616 is coupled between the V_{DDH} rail 630 and the internal V_{DDL} rail 632. A second resistor 618 is coupled between the V_{DDL} rail 632 and the V_{SS} rail 634. The resistances provided by resistors 616 and 618 may be configured to ensure that the voltage difference between the V_{DDL} rail 632 and V_{SS} rail 634 remains within the SOA limit defined for devices used to implement the RC clamps 602, 604. The resistances provided by resistors 616 and 618 may be further configured to ensure that the voltage difference between the V_{DDH} rail 630 and the V_{DDL} rail 632 lies within the SOA limit defined for devices used to implement the RC clamps 602, 604. In one example, the SOA limit defined for devices used to implement the RC clamps 602, 604 may be limited to a voltage range of less than 1.98V under all expected or anticipated operating conditions.

The RC network comprising resistor 616 and capacitor 612 and the RC network comprising resistor 618 and capacitor 612 act as low impedance dividers when a fast voltage ramp is applied to the V_{DDH} rail 630. These RC networks can help ensure that the V_{DDL} rail 632 follows the V_{DDH} rail 630.

A third stage 640c is configured to compensate for leakage associated with the effect of high temperatures on MOS devices within the RC clamps 602, 604. The leakage associated with the MOS devices at high temperature can pull the voltage of the V_{DDL} rail 634 towards the voltage of the V_{DDH} rail 630 if the load current is too small. A leakage compensation transistor 608 in the third stage 640c may be provided to provide a current path that serves to compensate for leakage at higher temperatures.

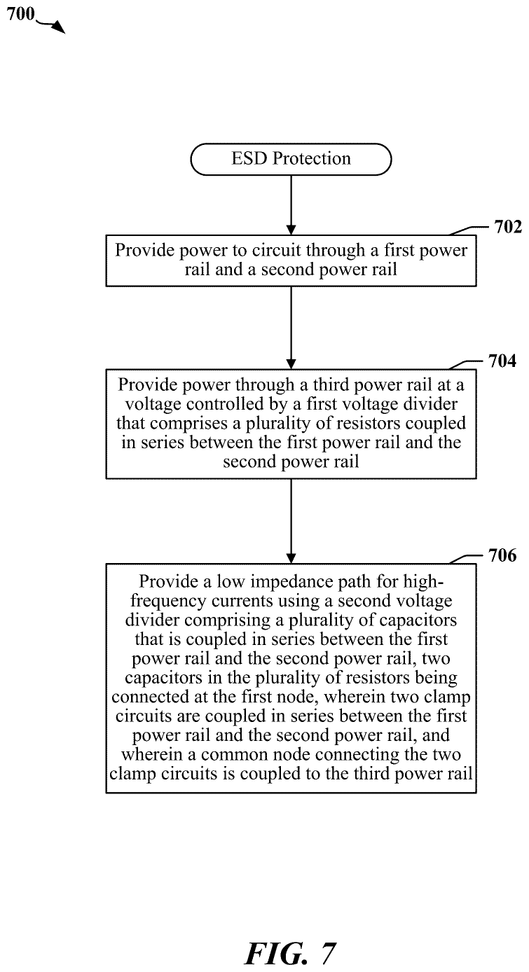

FIG. 7 is a flow diagram illustrating an example of a method 700 for providing ESD protection in an IC device in accordance with certain aspects disclosed herein. The method may relate to various features and aspects of the ESD protection circuits illustrated in FIGS. 4-6. At block 702, power may be provided to a circuit through a first power rail and a second power rail. The circuit may include one or more RC clamp circuits. At block 704, power may be provided through a third power rail at a voltage controlled by a first voltage divider. The first voltage divider may include a plurality of resistors coupled in series between the first power rail and the second power rail. At block 706, a low impedance path may be provided for high-frequency currents using a second voltage divider. The second voltage divider may include a plurality of capacitors coupled in series between the first power rail and the second power rail. Two capacitors in the plurality of capacitors may be connected through the first node. In some examples, two RC clamp circuits are coupled in series between the first power rail and the second power rail. A common node connecting the two clamp circuits may be coupled to the third power rail.

In some implementations, a first transistor is configured to provide the power through the third power rail. In one example, the first transistor has a drain coupled to the first power rail, a source coupled to the third power rail and a gate coupled to the first node. A resistive load may be coupled between the third power rail and the second power rail.

In some implementations, the method includes compensating for leakage in the first transistor using a second transistor. The second transistor may have a drain coupled to the third power rail. The second transistor may have a source and a gate coupled to the second power rail.

In some implementations, the method includes turning on a transistor switch when voltage difference between the first power rail and the second power rail is ramped from zero to a nominal operating voltage. The transistor switch may be configured to selectively couple a resistor between the third power rail and the second power rail. The transistor switch may be turned off when the first power rail is at a nominal operating voltage level.

In some implementations, a capacitor is coupled between the source of the first transistor and the second power rail. In one example, the second power rail is coupled to a ground reference (e.g., a V_{SS} rail).

It is noted that the operational steps described in any of the exemplary aspects herein are described to provide examples. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

In certain aspects, an apparatus performing certain functions disclosed herein may include means for clamping a power rail, means for providing power through an internal power rail, and means for providing a low impedance path for high-frequency currents. The means for clamping a first power rail may include two clamp circuits coupled in series between a first power rail and a second power rail. The means for providing power through an internal power rail may include a first voltage divider implemented using a plurality of resistors coupled in series between the first power rail and the second power rail. In one example, the means for providing a low impedance path for high-frequency currents may include a second voltage divider implemented using a plurality of capacitors coupled in series between the first power rail and the second power rail.

In certain implementations, the means for providing the power through the third power rail further includes a first transistor that has a drain coupled to the first power rail, a source coupled to the third power rail and a gate coupled to a first node at which two resistors in the plurality of resistors are connected.

In certain implementations, the apparatus further include means for compensating for leakage in the first transistor. In one example, the means for compensating for leakage may be implemented using a second transistor that has a drain coupled to the third power rail, and a source and a gate coupled to the second power rail.

In certain implementations, the apparatus further include means for varying a resistive load on the third power rail. In one example, the means for varying the resistive load may be implemented using a transistor switch that is configured to couple a resistor between the third power rail and the second power rail when voltage difference between the first power rail and the second power rail is ramped from zero to a nominal operating voltage.

In certain implementations, the apparatus further include means for shunting transients at the source of the first transistor to the second power rail. In one example, the means for shunting transients may be implemented by coupling a capacitor between the second power rail and the third power rail.

The apparatus may be deployed as an ESD protection circuit in an IC device. The ESD protection circuit may include a first voltage divider, and a second voltage divider a cascaded clamping circuit. The first voltage divider may be implemented using resistors. In one example, two resistors are connected through a first node are coupled in series between a first power rail and a second power rail. The sum of the resistances provided the resistors may lie within the megaohm range. The second voltage divider may be implemented using capacitors. In some instances, two capacitors are connected through a first node are coupled in series between a first power rail and a second power rail. The cascaded clamping circuit may be implemented using two clamp circuits coupled in series between the first power rail and the second power rail. The two clamp circuits may be connected through a second node. In some instances, a third power rail is coupled to the second node. The third power rail may be configured to operate at a voltage defined by the voltage at the first node.

In certain implementations, the ESD protection circuit includes a first transistor that has a drain coupled to the first power rail, a source coupled to the third power rail and a gate coupled to the first node. In certain implementations, the ESD protection circuit includes a second transistor that has a drain coupled to the third power rail, and a source and a gate coupled to the second power rail. In certain implementations, the ESD protection circuit provides a resistive load coupled between the third power rail and the second power rail. In certain implementations, the ESD protection circuit includes a resistor that is coupled between the third power rail and the second power rail through a transistor switch. The transistor switch may be turned on as voltage difference between the first power rail and the second power rail is ramped from zero to a nominal operating voltage.

In certain implementations, the ESD protection circuit includes a capacitor coupled between the source of the first transistor and the second power rail. The second power rail may provide a ground reference.

Some implementation examples are described in the following numbered clauses:
1. An electrostatic discharge protection circuit in an integrated circuit device, comprising: a first voltage divider comprising a plurality of resistors coupled in series between a first power rail and a second power rail, two resistors in the plurality of resistors being connected through a first node; a second voltage divider comprising a plurality of capacitors coupled in series between the first power rail and the second power rail, two capacitors in the plurality of capacitors being connected through the first node; and two clamp circuits coupled in series between the first power rail and the second power rail, wherein the two clamp circuits are connected through a second node, wherein a third power rail is coupled to the second node and has a voltage defined by voltage at the first node.
2. The electrostatic discharge protection circuit as described in clause 1, further comprising: a first transistor that has a drain coupled to the first power rail, a source coupled to the third power rail and a gate coupled to the first node.
3. The electrostatic discharge protection circuit as described in clause 2, further comprising: a second transistor that has a drain coupled to the third power rail, and a source and a gate coupled to the second power rail.
4. The electrostatic discharge protection circuit as described in clause 2 or clause 3, further comprising: a resistive load coupled between the third power rail and the second power rail.
5. The electrostatic discharge protection circuit as described in any of clauses 2-4, further comprising: a resistor coupled between the third power rail and the second power rail through a transistor switch.
6. The electrostatic discharge protection circuit as described in clause 5, wherein the transistor switch is turned on as voltage difference between the first power rail and the second power rail is ramped from zero to a nominal operating voltage.
7. The electrostatic discharge protection circuit as described in any of clauses 2-6, further comprising: a capacitor coupled between the source of the first transistor and the second power rail, wherein the second power rail is coupled to a ground reference.
8. The electrostatic discharge protection circuit as described in any of clauses 1-7, wherein the plurality of resistors provides a combined resistance that exceeds or equals 1 megaohm.
9. An apparatus, comprising: means for clamping a power rail, including two clamp circuits coupled in series between a first power rail and a second power rail; means for providing power through an internal power rail, comprising a first voltage divider that comprises a plurality of resistors coupled in series between the first power rail and the second power rail; and means for providing a low impedance path for high-frequency currents, including a second voltage divider comprising a plurality of capacitors coupled in series between the first power rail and the second power rail.
10. The apparatus as described in clause 9, wherein the means for providing power through the internal power rail further comprises: a first transistor that has a drain coupled to the first power rail, a source coupled to the internal power rail and a gate coupled to a first node at which two resistors in the plurality of resistors are connected.
11. The apparatus as described in clause 10, further comprising: means for compensating for leakage in the first transistor, including a second transistor that has a drain coupled to the internal power rail, and a source and a gate coupled to the second power rail.
12. The apparatus as described in clause 10 or clause 11, further comprising: means for varying a resistive load on the internal power rail, including a transistor switch that is configured to couple a resistor between the internal power rail and the second power rail when voltage difference between the first power rail and the second power rail is ramped from zero to a nominal operating voltage.
13. The apparatus as described in any of clauses 10-12, wherein the resistive load includes a resistor coupled between the internal power rail and the second power rail.
14. The apparatus as described in any of clauses 10-13, further comprising: means for shunting transients at the source of the first transistor to the second power rail.
15. A method for providing electrostatic discharge protection in an integrated circuit device, comprising: providing power to a circuit through a first power rail and a second power rail; providing power through a third power rail at a voltage controlled by a first voltage divider that comprises a plurality of resistors coupled in series between the first power rail and the second power rail; and providing a low impedance path for high-frequency currents using a second voltage divider comprising a plurality of capacitors that is coupled in series between the first power rail and the second power rail, two capacitors in the plurality of capacitors being connected through a first node, wherein two clamp circuits are coupled in series between the first power rail and the second power rail, and wherein a second node connecting the two clamp circuits is coupled to the third power rail.
16. The method as described in clause 15, wherein a first transistor is configured to provide the power through the third power rail, the first transistor having a drain coupled to the first power rail, a source coupled to the third power rail and a gate coupled to the first node.
17. The method as described in clause 16, further comprising: compensating for leakage in the first transistor using a second transistor that has a drain coupled to the third power rail, and a source and a gate coupled to the second power rail.
18. The method as described in clause 16 or clause 17, wherein a resistive load is coupled between the third power rail and the second power rail.
19. The method as described in any of clauses 16-18, further comprising: turning on a transistor switch that is configured to couple a resistor between the third power rail and the second power rail when voltage difference between the first power rail and the second power rail is ramped from zero to a nominal operating voltage; and turning off the transistor switch when the first power rail is at a nominal operating voltage level.
20. The method as described in any of clauses 16-20, wherein a capacitor is coupled between the source of the first transistor and the second power rail, wherein the second power rail is coupled to a ground reference.

The present disclosure is provided to enable any person skilled in the art to make or use aspects of the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. An electrostatic discharge protection circuit in an integrated circuit device, comprising:
a first voltage divider comprising a plurality of resistors coupled in series between a first power rail and a second power rail, two resistors in the plurality of resistors being connected through a first node;
a second voltage divider comprising a plurality of capacitors coupled in series between the first power rail and the second power rail, two capacitors in the plurality of capacitors being connected through the first node; and
two clamp circuits coupled in series between the first power rail and the second power rail, wherein the two clamp circuits are connected through a second node,
wherein a third power rail is coupled to the second node and has a voltage defined by voltage at the first node.

2. The electrostatic discharge protection circuit of claim 1, further comprising:
a first transistor that has a drain coupled to the first power rail, a source coupled to the third power rail and a gate coupled to the first node.

3. The electrostatic discharge protection circuit of claim 2, further comprising:
a second transistor that has a drain coupled to the third power rail, and a source and a gate coupled to the second power rail.

4. The electrostatic discharge protection circuit of claim 2, further comprising:
a resistive load coupled between the third power rail and the second power rail.

5. The electrostatic discharge protection circuit of claim 2, further comprising:
a resistor coupled between the third power rail and the second power rail through a transistor switch.

6. The electrostatic discharge protection circuit of claim 5, wherein the transistor switch is turned on as voltage difference between the first power rail and the second power rail is ramped from zero to a nominal operating voltage.

7. The electrostatic discharge protection circuit of claim 2, further comprising:
a capacitor coupled between the source of the first transistor and the second power rail, wherein the second power rail is coupled to a ground reference.

8. The electrostatic discharge protection circuit of claim 1, wherein the plurality of resistors provides a combined resistance that exceeds or equals 1 megaohm.

9. An apparatus, comprising:
means for clamping a power rail, including two clamp circuits coupled in series between a first power rail and a second power rail;
means for providing power through an internal power rail, comprising a first voltage divider that comprises a plurality of resistors coupled in series between the first power rail and the second power rail; and
means for providing a low impedance path for high-frequency currents, including a second voltage divider comprising a plurality of capacitors coupled in series between the first power rail and the second power rail.

10. The apparatus of claim 9, wherein the means for providing power through the internal power rail further comprises:
a first transistor that has a drain coupled to the first power rail, a source coupled to the internal power rail and a gate coupled to a first node at which two resistors in the plurality of resistors are connected.

11. The apparatus of claim 10, further comprising:
means for compensating for leakage in the first transistor, including a second transistor that has a drain coupled to the internal power rail, and a source and a gate coupled to the second power rail.

12. The apparatus of claim 10, further comprising:
means for varying a resistive load on the internal power rail, including a transistor switch that is configured to couple a resistor between the internal power rail and the second power rail when voltage difference between the first power rail and the second power rail is ramped from zero to a nominal operating voltage.

13. The apparatus of claim 12, wherein the resistive load includes a resistor coupled between the internal power rail and the second power rail.

14. The apparatus of claim 10, further comprising:
means for shunting transients at the source of the first transistor to the second power rail.

15. A method for providing electrostatic discharge protection in an integrated circuit device, comprising:
providing power to a circuit through a first power rail and a second power rail;
providing power through a third power rail at a voltage controlled by a first voltage divider that comprises a plurality of resistors coupled in series between the first power rail and the second power rail; and
providing a low impedance path for high-frequency currents using a second voltage divider comprising a plurality of capacitors that is coupled in series between the first power rail and the second power rail, two capacitors in the plurality of capacitors being connected through a first node,
wherein two clamp circuits are coupled in series between the first power rail and the second power rail, and wherein a second node connecting the two clamp circuits is coupled to the third power rail.

16. The method of claim 15, wherein a first transistor is configured to provide the power through the third power rail, the first transistor having a drain coupled to the first power rail, a source coupled to the third power rail and a gate coupled to the first node.

17. The method of claim 16, further comprising:
compensating for leakage in the first transistor using a second transistor that has a drain coupled to the third power rail, and a source and a gate coupled to the second power rail.

18. The method of claim 16, wherein a resistive load is coupled between the third power rail and the second power rail.

19. The method of claim 16, further comprising:
turning on a transistor switch that is configured to couple a resistor between the third power rail and the second power rail when voltage difference between the first power rail and the second power rail is ramped from zero to a nominal operating voltage; and
turning off the transistor switch when the first power rail is at a nominal operating voltage level.

20. The method of claim 16, wherein a capacitor is coupled between the source of the first transistor and the second power rail, wherein the second power rail is coupled to a ground reference.
